(19) United States
(12) Patent Application Publication
(10) Pub. No.: US 2013/0248942 A1
(43) Pub. Date: Sep. 26, 2013

(54) SEMICONDUCTOR DEVICE AND METHOD FOR MANUFACTURING SEMICONDUCTOR DEVICE

(71) Applicant: KABUSHIKI KAISHA TOSHIBA, Tokyo (JP)

(72) Inventor: Kimitoshi OKANO, Mie (JP)

(73) Assignee: KABUSHIKI KAISHA TOSHIBA, Tokyo (JP)

(21) Appl. No.: 13/800,498

(22) Filed: Mar. 13, 2013

(30) Foreign Application Priority Data
Mar. 21, 2012 (JP) 2012-063461

(51) Int. Cl. H01L 29/04; H01L 21/02; H01L 29/78

(52) U.S. Cl. CPC H01L 29/045; H01L 29/785; H01L 21/02609
USPC 257/255; 438/478

(57) ABSTRACT

According to one embodiment, a semiconductor device includes a channel region formed on a first side surface of a fin-type semiconductor and a source/drain region formed on a second side surface, plane orientation of which is different from that of the first side surface, so that the channel region is interposed in the fin-type semiconductor.

### CROSS-REFERENCE TO RELATED APPLICATIONS

This application is based upon and claims the benefit of priority from Japanese Patent Application No. 2012-63461, filed on Mar. 21, 2012; the entire contents of which are incorporated herein by reference.

### FIELD

Embodiments described herein relate generally to a semiconductor device and a method for manufacturing a semiconductor device.

### BACKGROUND

In a fin transistor, a (100) plane or a (110) plane is most frequently considered as a channel plane orientation of a fin side surface. In a fin transistor, in terms of channel carrier mobility, it is deemed good to use a (100) plane for an N-channel transistor and a (110) plane for a P-channel transistor. On the other hand, the plane orientation of the fin side surface in the source/drain region has generally been identical to the plane orientation of the fin side surface in the channel region.

### BRIEF DESCRIPTION OF THE DRAWINGS

FIG. 1A is a top view illustrating a schematic configuration of a semiconductor device according to a first embodiment, FIG. 1B is a cross-sectional view taken along line A-A of FIG. 1A, and FIG. 1C is a cross-sectional view taken along line B-B of FIG. 1A;

FIG. 2 is a top view illustrating angles of deviation of a fin side surface from a (100) plane in the semiconductor device of FIG. 1A;

FIG. 3A is a top view illustrating a method for manufacturing a semiconductor device according to a second embodiment, and FIG. 3B is a cross-sectional view taken along line C-C of FIG. 3A;

FIG. 4A is a top view illustrating the method for manufacturing the semiconductor device according to the second embodiment, and FIG. 4B is a cross-sectional view taken along line C-C of FIG. 4A;

FIG. 5A is a top view illustrating the method for manufacturing the semiconductor device according to the second embodiment, and FIG. 5B is a cross-sectional view taken along line C-C of FIG. 5A;

FIG. 6A is a top view illustrating the method for manufacturing the semiconductor device according to the second embodiment, and FIG. 6B is a cross-sectional view taken along line C-C of FIG. 6A;

FIG. 7A is a top view illustrating the method for manufacturing the semiconductor device according to the second embodiment, and FIG. 7B is a cross-sectional view taken along line C-C of FIG. 7A;

FIG. 8A is a top view illustrating the method for manufacturing the semiconductor device according to the second embodiment, and FIG. 8B is a cross-sectional view taken along line C-C of FIG. 8A;

FIG. 9A is a top view illustrating the method for manufacturing the semiconductor device according to the second embodiment, and FIG. 9B is a cross-sectional view taken along line C-C of FIG. 9A;

FIG. 10A is a top view illustrating the method for manufacturing the semiconductor device according to the second embodiment, and FIG. 10B is a cross-sectional view taken along line C-C of FIG. 10A;

FIG. 11 is a top view illustrating a schematic configuration of a semiconductor device according to a third embodiment;

FIG. 12 is a top view illustrating a schematic configuration of a semiconductor device according to a fourth embodiment;

FIGS. 13A to 13C are top views illustrating a method for manufacturing a semiconductor device according to a fifth embodiment; and

FIG. 14A is a top view illustrating a schematic configuration of a semiconductor device according to a sixth embodiment, FIG. 14B is a cross-sectional view taken along line D-D of FIG. 14A, and FIG. 14C is a cross-sectional view taken along line E-E of FIG. 14A.

### DETAILED DESCRIPTION

A semiconductor device according to an embodiment is provided with a channel region and a source/drain region. The channel region is formed on a first side surface of a fin-type semiconductor. The source/drain region is formed on a second side surface, the plane orientation of which is different from that of the first side surface, so that the channel region of the fin-type semiconductor is interposed.

Hereinafter, semiconductor devices according to embodiments will be described with reference to the drawings. Also, the present invention is not limited by the following embodiments.

### First Embodiment

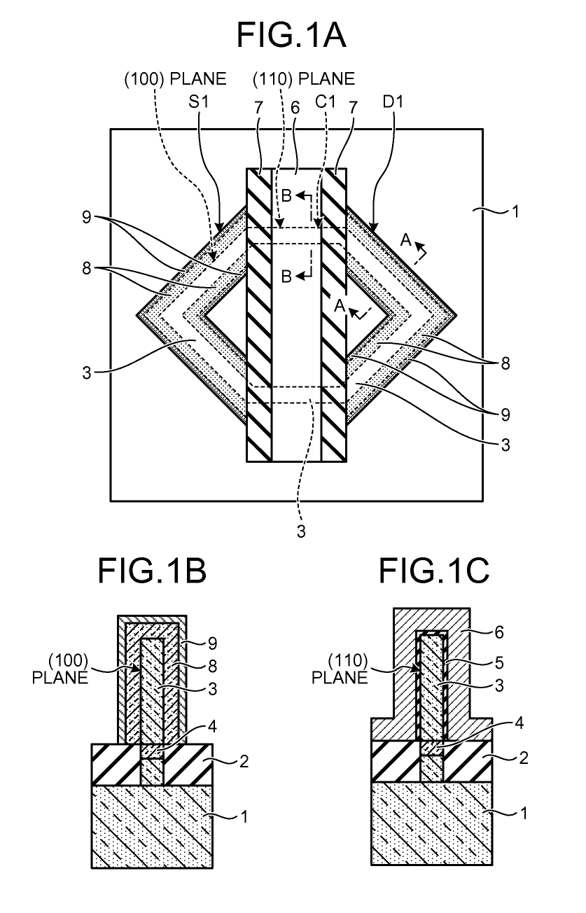

FIG. 1A is a top view illustrating a schematic configuration of a semiconductor device according to a first embodiment, FIG. 1B is a cross-sectional view taken along line A-A of FIG. 1A, and FIG. 1C is a cross-sectional view taken along line B-B of FIG. 1A.

Referring to FIGS. 1A to 1C, a fin-type semiconductor 3 is formed on a semiconductor substrate 1. Materials of the semiconductor substrate 1 and the fin-type semiconductor 3 may be selected from, for example, Si, Ge, SiGe, GaAs, AlGaAs, InP, GaP, InGaAs, GaN, and SiC. Also, the materials of the semiconductor substrate 1 and the fin-type semiconductor 3 may be identical to each other or different from each other.

The fin-type semiconductor 3 is, in this case, configured so that the plane orientation of the fin side surface has a (110) plane and a (100) plane. This configuration enables the plane orientation to have a (100) plane on the fin side surface, by bending the fin side surface by 45° with regard to the fin side surface of the (110) plane, so as to be continuous with the (110) plane. It is also possible to configure the fin-type semiconductor 3 in a loop shape so as to define a hexagon.

Then, a buried insulation layer 2 is formed on the semiconductor substrate 1 so that the lower portion of the fin-type semiconductor 3 is buried. It is possible to use, as the structure of the buried insulation layer 2, an STI (Shallow Trench Isolation) structure, for example. Also, it is possible to use, as the material of the buried insulation layer 2, SiO₂, for example.

In the fin side surface of the fin-type semiconductor 3 protruding from the buried insulation layer 2, a channel region C1 is formed on the (110) plane, and a source region S1 and a drain region D1 are formed on the (100) plane so as to interpose the channel region C1.

In the channel region C1, a gate electrode 6 is formed, via a gate insulation film 5, so as to interpose the fin-type semiconductor 3. Also, side wall spacers 7 are formed on side surfaces of the gate electrode 6.

Also, in the channel region C1 of the fin-type semiconductor 3, it is preferred to reduce the impurity concentration of the channel region C1, in order to suppress fluctuation of electric characteristics of the field-effect transistor and degradation of carrier mobility in the channel region. The channel region C1 may be non-doped. Even when the impurity concentration inside the channel region C1 has been reduced sufficiently, the fin width is preferably made smaller than the gate length, more specifically ⅔ or less, in order to suppress a short-channel effect. Sufficient reduction of impurity concentration inside the channel region C1 may also make the fin-type transistor a fully-depleted device.

As the material of the gate electrode 6, polycrystalline silicon, for example, may be used. Alternatively, the material of the gate electrode 6 may also be selected from, for example, W, Al, TaN, Ru, TiAlN, HfN, NiSi, Mo, and TiN. Also, the material of the gate insulation film 5 may be selected from, for example, SiO₂, HfO, HfSiO, HfSᵢON, HfAlO, HfAlSᵢON, and La₂O₃. Also, as the material of the side wall spacers 7, an insulating substance, such as Si₃N₄, may be used.

Also, in the source region S1 and the drain region D1, a high-concentration impurity diffusion layer is formed on the fin-type semiconductor 3. This high-concentration impurity diffusion layer may be an N⁺-type impurity diffusion layer in the case of a fin-type N channel field-effect transistor, or may be a P⁺-type impurity diffusion layer in the case of a fin-type P-channel field-effect transistor. In the source region S1 and the drain region D1, a semiconductor layer 8 is formed so as to surround the fin-type semiconductor 3,in order to reduce parasitic resistance in the source and drain region of the fin-type field-effect transistor. The semiconductor layer 8 may be a monocrystalline semiconductor, may be a polycrystalline semiconductor, or may be an amorphous semiconductor. The material of the semiconductor layer 8 may also be selected from, for example, Si, Ge, SiGe, GaAs, AlGaAs, InP, GaP, InGaAs, GaN, and SiC. A silicide layer 9 is formed on the outer layer of the semiconductor layer 8. As the silicide layer 9, it is possible to use, for example, WSi, MoSi, NiSi, or NiPtSi.

Furthermore, a punch-through stopper layer 4 is formed on the lower portion of the fin-type semiconductor 3 so as to prevent any flow of leakage current between the source region S1 and the drain region D1 due to absence of the gate electrode 6 on the fin side surface. When the source region S1 and the drain region D1 are N⁺-type impurity diffusion layers, the punch-through stopper layer 4 may be a P⁻-type impurity diffusion layer. When the source region S1 and the drain region D1 are P⁺-type impurity diffusion layers, the punch-through stopper layer 4 may be an N⁻-type impurity diffusion layer.

In this case, the channel plane orientation of the fin side surface of the channel region C1 is defined by a (110) plane, making it possible to increase the mobility of holes, compared with a case of defining the channel plane orientation by a (100) plane, and thus to accomplish high performance of the fin-type P-channel field-effect transistor.

Furthermore, the plane orientation of the fin side surface of the source region S1 and the drain region D1 is defined by a (100) plane so that, even if the semiconductor layer 8 is formed on the fin side surface of the source region S1 and the drain region D1 by selective epitaxial growth, formation of a facet, which consists of a (111) plane, on the fin side surface of the source region S1 and the drain region D1 may be suppressed. Therefore, the thickness of the semiconductor layer 8 from the fin side surface may be made uniform so that, even when the silicide layer 9 is formed on the semiconductor layer 8, any approach between the silicide layer 9 and PN junctions of bottom portions of the source region S1 and the drain region D1 may be prevented. As a result, any increase of junction leakage of the fin-type P-channel field-effect transistor may be suppressed.

Furthermore, formation of a facet, which consists of a (111) plane, on the fin side surface of the source region S1 and the drain region D1 is prevented so that, even when an interlayer insulating film is deposited after formation of the silicide layer 9, any formation of voids on the lower portion of the semiconductor layer 8 may be suppressed. This makes it possible to prevent metal from being buried in voids during a contact forming process, which follows formation of the interlayer insulating film, and thus to suppress any junction leakage current resulting from metal residues.

Furthermore, formation of a facet, which consists of a (111) plane, on the fin side surface of the source region S1 and the drain region D1 is prevented, thereby making it possible to deposit a film of metal, which is used for the silicide layer 9, on whole surface of the semiconductor layer 8 even by a method of poor coverage characteristics, such as sputtering, and thus to accomplish reduction of contact resistance between the silicide layer 9 and source and drain diffusion layers.

In the case of a fin-type N channel field-effect transistor, furthermore, when the channel plane orientation of the fin side surface of the channel region C1 is defined by a (110) plane, the electron mobility is greatly improved by stress engineering, compared with a case of defining the plane orientation by a (100) plane, thereby making it possible to accomplish high performance comparable or superior to that when the channel plane orientation of the fin side surface of the channel region C1 is defined by a (100) plane. Therefore, (110) channel plane orientation, in combination with stress engineering, is promising for realizing high performance fin-type N-channel and P-channel field-effect transistors simultaneously.

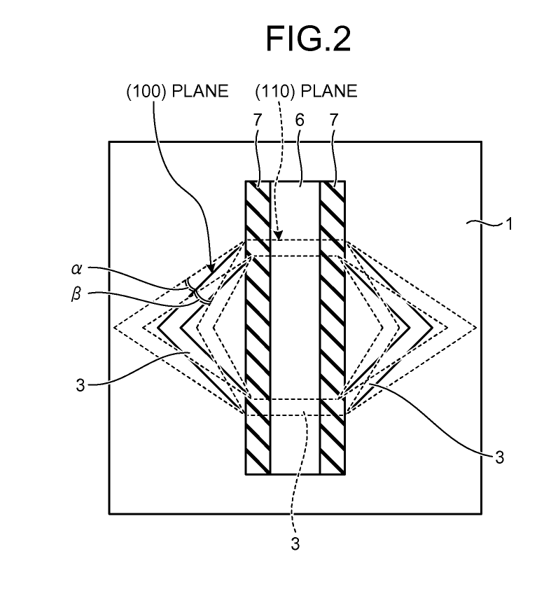

FIG. 2 is a top view illustrating angles of deviation, from the (100) plane, of a side surface of the fin-type semiconductor 3 of the source region S1 and the drain region D1 of the semiconductor device of FIG. 1A.

Referring to FIG. 2, in connection with suppression of formation of a facet, which consists of a (111) plane, on the fin side surface of the source region S1 and the drain region D1, the plane orientation of the fin side surface of the source region S1 and the drain region D1 is not required to exactly coincide with the (100) plane, but the angles α and β of deviation of the fin side surface from the (100) plane need only to be equal to or less than 15°. When these angles α and β of deviation are equal to or less than 15°, formation of a facet, which consists of a (111) plane, on the side surface of the semiconductor layer 3 as a result of epitaxial growth may be sufficiently suppressed, thereby solving the problem, for example, of formation of voids on the lower portion of the semiconductor layer 8.

### Second Embodiment

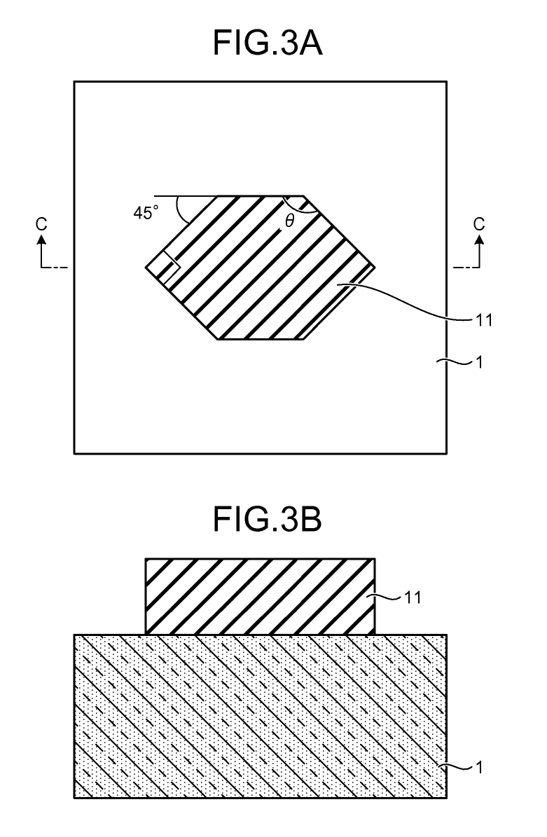

FIGS. 3A to 10A are top views illustrating a method for manufacturing a semiconductor device according to a second embodiment, and FIGS. 3B to 10B are cross-sectional views taken along line C-C of FIGS. 3A to 10A, respectively.

Referring to FIGS. 3A and 3B, a core pattern 11 is formed on a semiconductor substrate 1. The core pattern 11 may have at least some of its internal angles θ set as obtuse angles. For example, when the core pattern 11 is a hexagon, four internal angles may be set so that adjacent sides are bent by 45°, and two remaining internal angles, which are opposite to each other, may be 90°. As the material of the core pattern 11, a resist material may be used, or a hard mask material, such as BSG film or silicon nitride film, may be used.

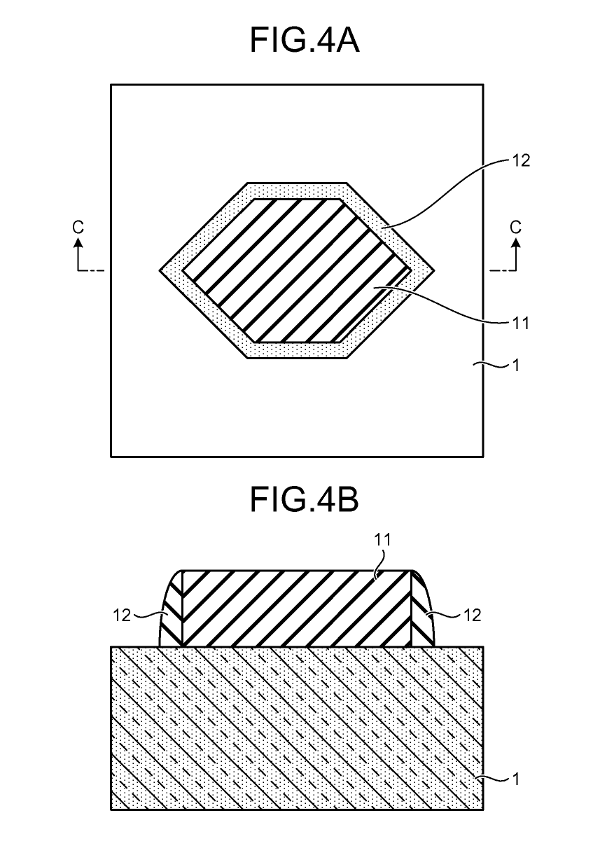

Next, as illustrated in FIGS. 4A and 4B, a side wall material, which has a high degree of etching selectivity with regard to the core pattern 11, is deposited onto the entire surface on the semiconductor substrate 1, including the side surface of the core pattern 11, using a method such as CVD, for example. When the core pattern 11 is made of BSG film, for example, silicon nitride film may be used as the side wall material, which has a high degree of etching selectivity with regard to the core pattern 11. Then, anisotropic etching of the side wall material is performed so that, by exposing the semiconductor substrate 1 while leaving the side wall material on the side surface of the core pattern 11, a side wall pattern 12 is formed on the side surface of the core pattern 11.

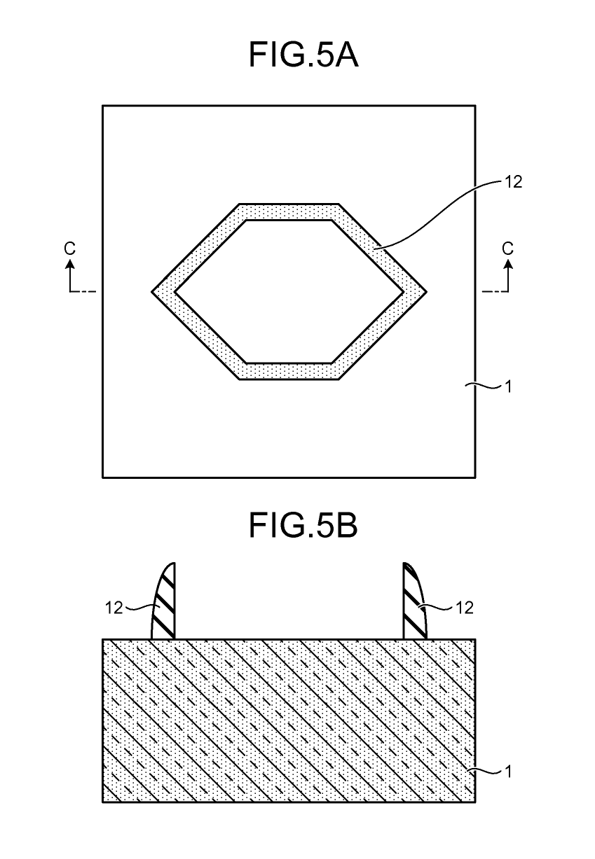

Next, as illustrated in FIGS. 5A and 5B, the core pattern 11 is removed from the semiconductor substrate 1 while leaving the side wall pattern 12 on the semiconductor substrate 1.

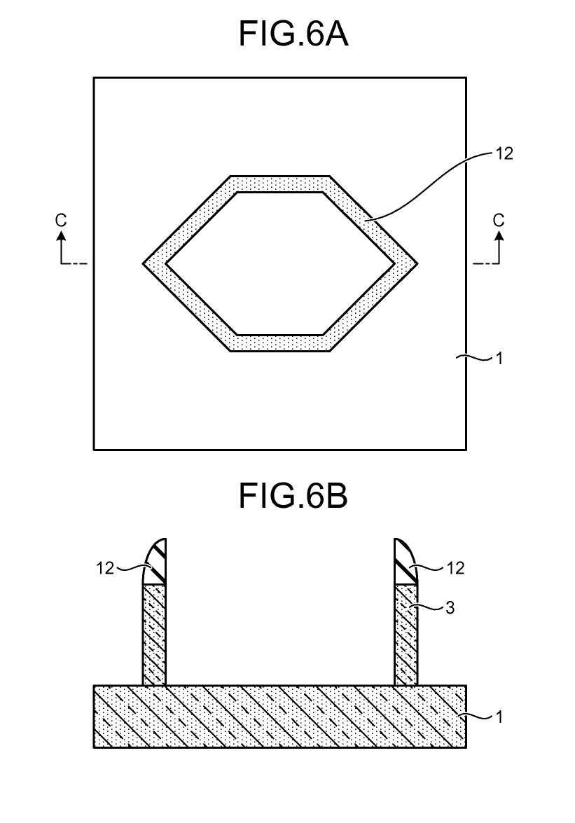

Next, as illustrated in FIGS. 6A and 6B, the semiconductor substrate 1 is etched, using the side wall pattern 12 as a mask, so that a fin-type semiconductor 3 is formed on the semiconductor substrate 1 as a result of transfer of the side wall pattern 12.

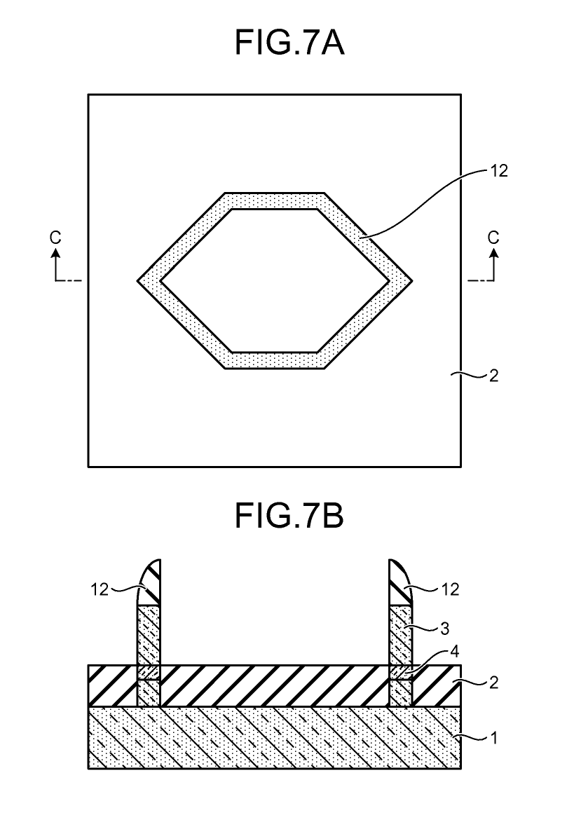

Next, as illustrated in FIGS. 7A and 7B, a buried insulation layer 2 is formed on the semiconductor substrate 1, using a method such as CVD, so that the fin-type semiconductor 3 is buried. The buried insulation layer 2 is then etched so that the upper portion of the fin-type semiconductor 3 is exposed from the buried insulation layer 2, while the lower portion of the fin-type semiconductor 3 is buried in the buried insulation layer 2.

Next, impurities are vertically implanted into the buried insulation layer 2 by ion implantation. At this time, the implanted impurity ions undergo large-angle scattering with a predetermined probability on the outer layer of the buried insulation layer so that, as the impurity ions are doped on the lower portion of the fin-type semiconductor 3, a punch-through stopper layer 4 is formed on the lower portion of the fin-type semiconductor 3.

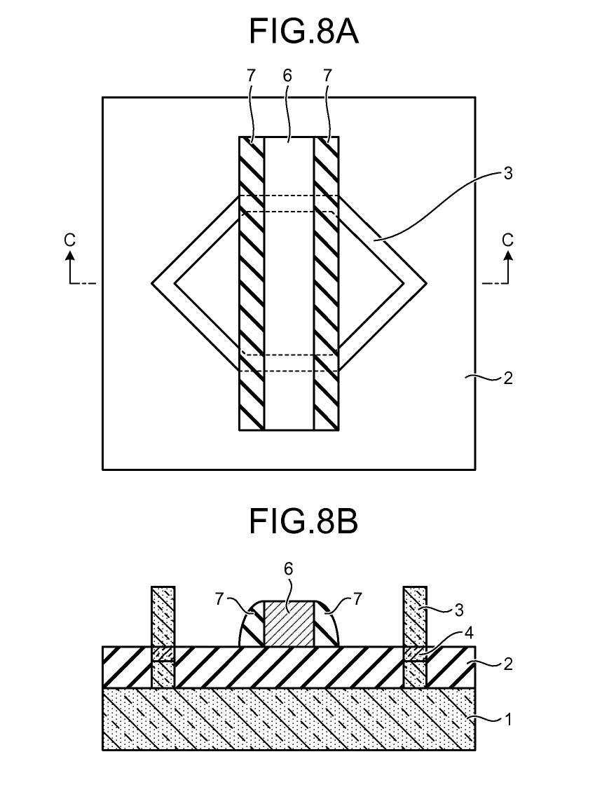

Next, a gate insulation film 5 is formed on the side surface of the fin-type semiconductor 3, which protrudes from the buried insulation layer 2; then, as illustrated in FIGS. 8A and 8B, a gate electrode 6 is formed, via the gate insulation film 5, so as to interpose the fin-type semiconductor 3; and a side wall spacer 7 is formed on the side surface of the gate electrode 6.

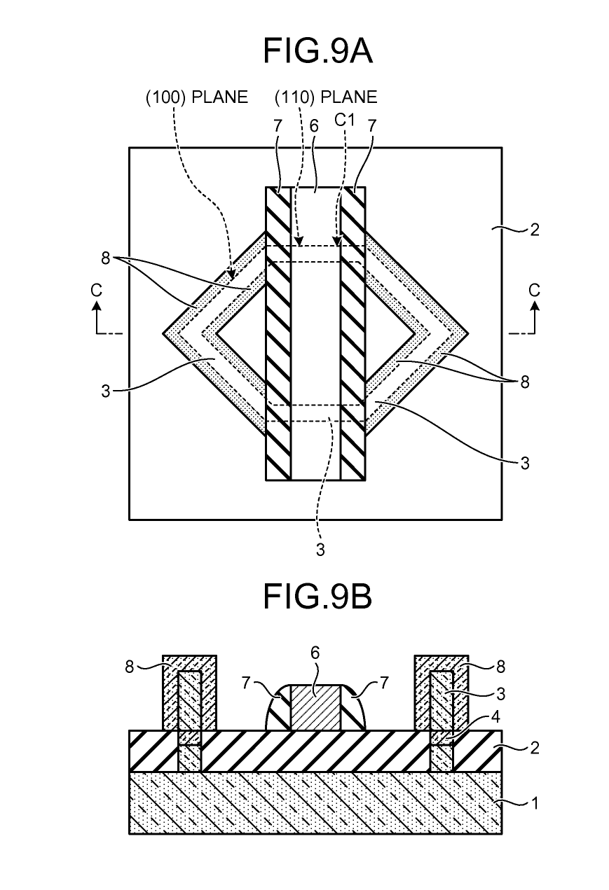

Next, as illustrated in FIGS. 9A and 9B, impurities are implanted obliquely into the source region S1 and the drain region D1 of the fin-type semiconductor 3 by ion implantation so that a high-concentration impurity diffusion layer is formed in the source region S1 and the drain region D1 of the fin-type semiconductor 3. A semiconductor layer 8 is then formed in the source region S1 and the drain region D1 of the fin-type semiconductor 3 by selective epitaxial growth. Next, high-concentration impurities are doped into the semiconductor layer 8 by ion implantation.

In the source region S1 and the drain region D1, the plane orientation of the fin side surface is defined by a (100) plane. This guarantees that, even when selective epitaxial growth of the semiconductor layer 8 is performed, formation of a facet, which consists of a (111) plane, on the semiconductor layer 8 may be prevented, and the thickness of the semiconductor layer 8 from the fin side surface may be made uniform.

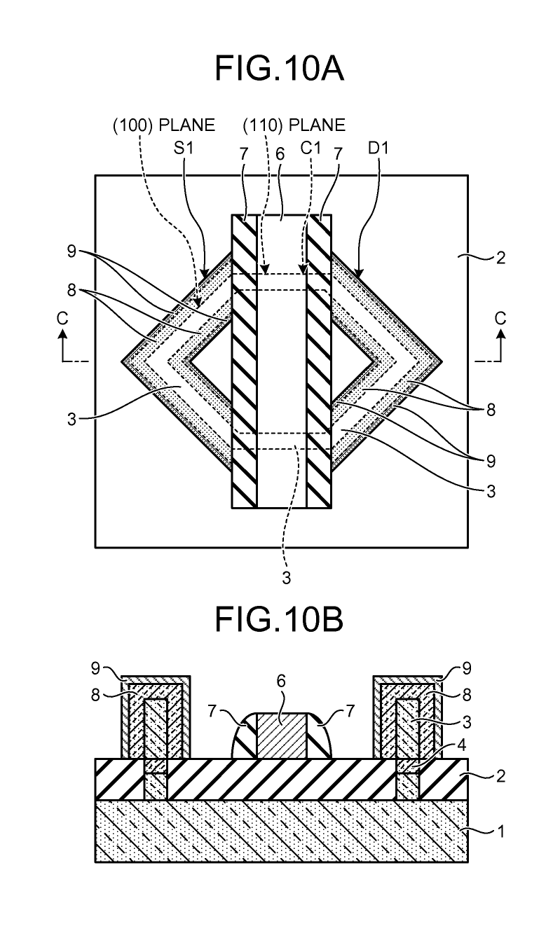

Next, as illustrated in FIGS. 10A and 10B, a metal film is deposited on the semiconductor layer 8 by a method such as CVD or sputtering. The metal film is then subjected to heat treatment so that the outer layer of the semiconductor layer 8 turns into silicide, thereby forming a silicide layer 9 on the outer layer of the semiconductor layer 8.

### Third Embodiment

FIG. 11 is a top view illustrating a schematic configuration of a semiconductor device according to a third embodiment.

Referring to FIG. 11, the semiconductor device is provided, instead of the fin-type semiconductor 3, the semiconductor layer 8, and the silicide layer 9 of the semiconductor device of FIG. 1A, with a fin-type semiconductor 3′, a semiconductor layer 8′, and a silicide layer 9′.

The fin-type semiconductor 3 of FIG. 1A is bent at boundaries between the side wall spacers 7 and the source region S1 and at boundaries between the side wall spacers 7 and the drain region D1. In contrast, the fin-type semiconductor 3′ of FIG. 11 is bent at boundaries between the side wall spacers 7 and the gate electrode 6. In connection with the fin side surface of the fin-type semiconductor 3′, then, the gate electrode 6 is formed on the (110) plane, and the side wall spacers 7 are formed on the (100) plane. Furthermore, the semiconductor layer 8′ is formed on the (100) plane, which is exposed from the side wall spacers 7, so as to surround the fin-type semiconductor 3′. The silicide layer 9′ is formed on the outer layer of the semiconductor layer 8′.

In this case, the channel plane orientation of the fin side surface, on which the gate electrode 6 is arranged, is defined by the (110) plane so that high performance of the fin-type P-channel field-effect transistor may be accomplished. Also, the plane orientation of the fin side surface, on which the semiconductor layer 8′ is formed, is defined by the (100) plane so that the thickness of the semiconductor layer 8′ from the fin side surface may be made uniform.

### Fourth Embodiment

FIG. 12 is a top view illustrating a schematic configuration of a semiconductor device according to a fourth embodiment.

Referring to FIG. 12, the semiconductor device is provided, instead of the fin-type semiconductor 3, the semiconductor layer 8, and the silicide layer 9 of the semiconductor device of FIG. 1A, with a fin-type semiconductor 3″, a semiconductor layer 8″, and a silicide layer 9″.

In this case, the fin-type semiconductor 3″ is bent at boundaries between the side wall spacers 7 and the source region S1 and at boundaries between the side wall spacers 7 and the drain region D1 so that curved lines are drawn in the source region S1 and the drain region D1. These curved lines may be semi-circular or semi-elliptical. In the source region S1 and the drain region D1, then, the semiconductor layer 8″ is formed so as to surround the fin-type semiconductor 3″. The silicide layer 9″ is formed on the outer layer of the semiconductor layer 8″.

In this case, the fin-type semiconductor 3″ is configured to draw curved lines in the source region S1 and the drain region D1 so that the region of fin side surface with (110) plane, on which the semiconductor layer 8″ is formed, may be reduced. This suppresses formation of a facet, which consists of a (111) plane, on the side surface of the semiconductor layer 8″ as a result of epitaxial growth, thereby solving the problem, for example, of formation of voids on the lower portion of the semiconductor layer 8″.

### Fifth Embodiment

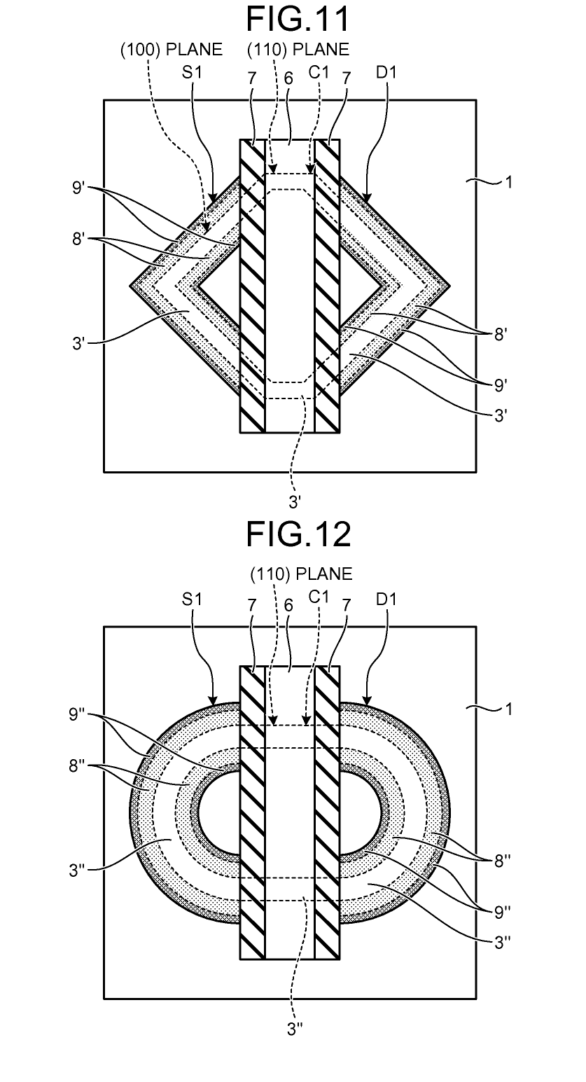

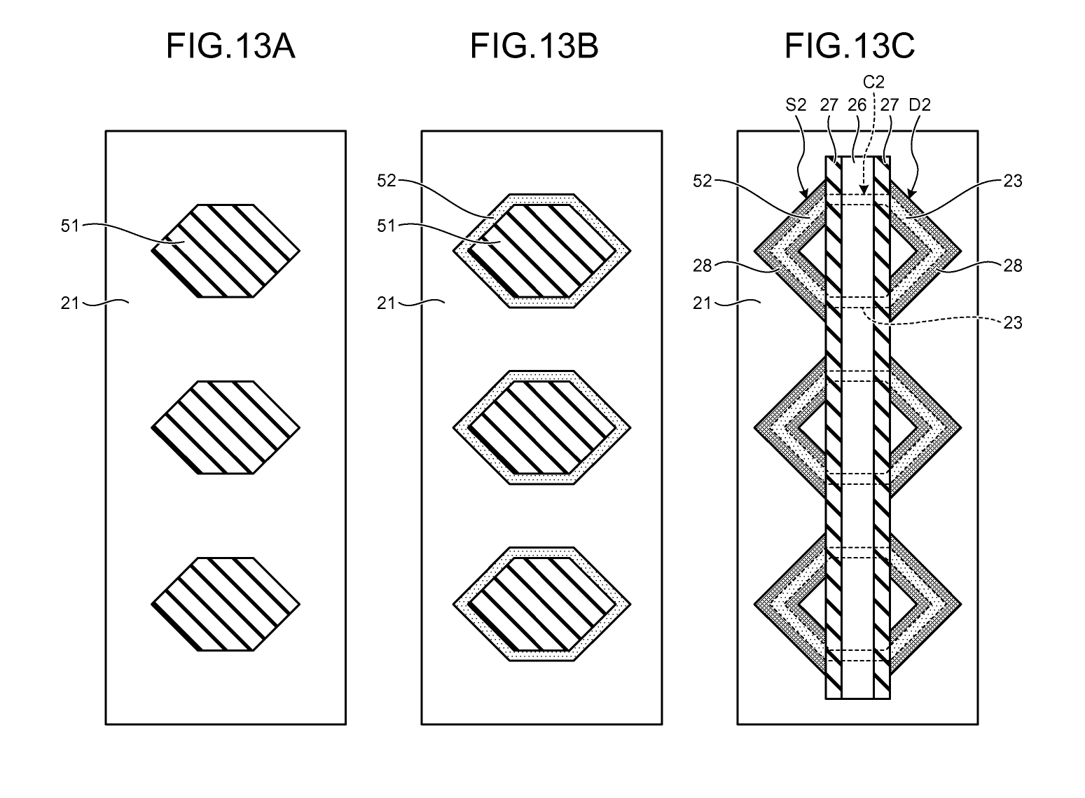

FIGS. 13A to 13C are top views illustrating a method for manufacturing a semiconductor device according to a fifth embodiment.

Referring to FIG. 13A, core patterns 51 are formed on a semiconductor substrate 21. In this case, it is possible to arrange three core patterns 51 in parallel on the semiconductor substrate 21. Furthermore, each core pattern 51 may be formed in the same manner as in the case of the core pattern 11 of FIG. 3A.

Next, as illustrated in FIG. 13B, a side wall pattern 52 is formed on the side surface of each core pattern 51. Furthermore, each side wall pattern 52 may be formed in the same manner as in the case of the side wall pattern 12 of FIG. 4A.

Next, as illustrated in FIG. 13C, fin-type semiconductors 23 are formed on the semiconductor substrate 21 in the same method as in the case of FIGS. 5A to 6A, and a gate electrode 26 is then formed on the (110) plane of the fin side surface of the fin-type semiconductors 23. Side wall spacers 27 are then formed on side surfaces of the gate electrode 26. Also, the gate electrode 26 and the side wall spacers 27 may be shared by the three fin-type field-effect transistors formed on the semiconductor substrate 21. Next, a semiconductor layer 28 is formed in the source region S2 and the drain region D2 of each fin-type semiconductor 23 so that the fin-type semiconductor 23 is surrounded.

Although a method of arranging three fin-type field-effect transistors in parallel has been described with regard to the example of FIG. 13C, it is also possible to arrange two in parallel or to arrange four or more in parallel.

### Sixth Embodiment

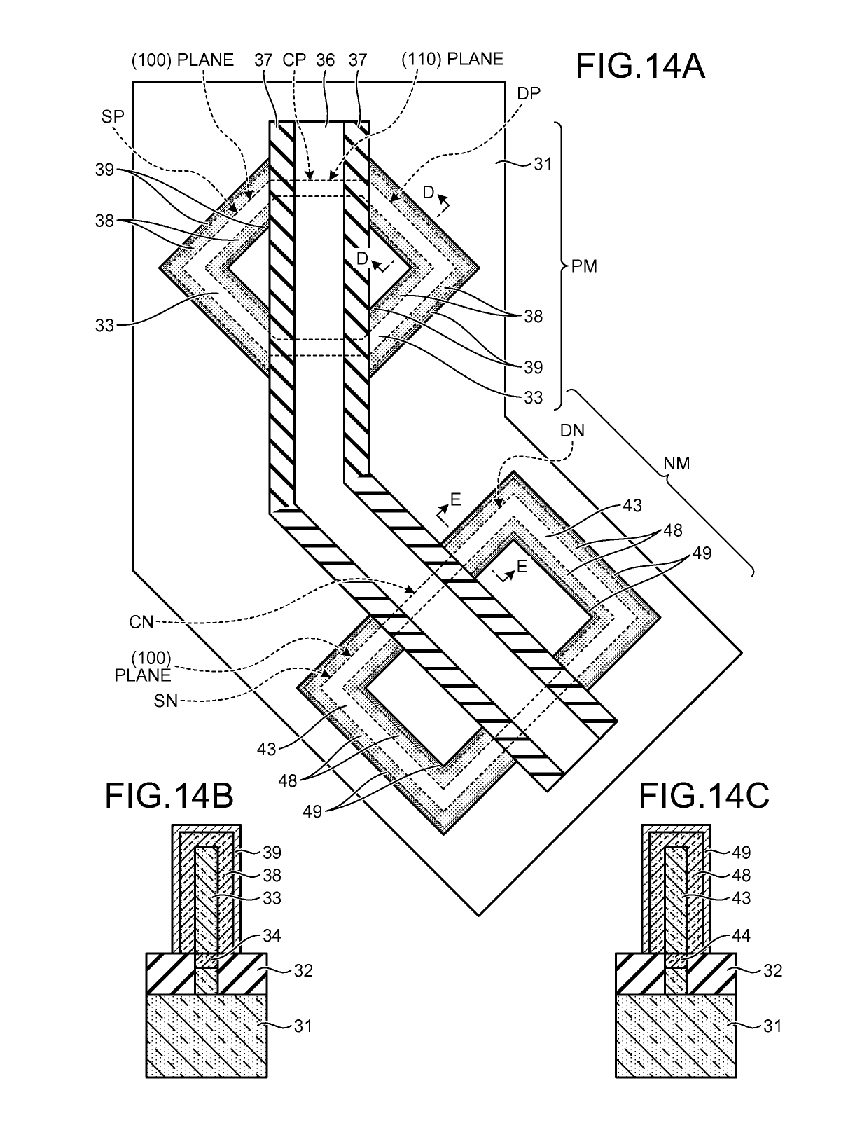

FIG. 14A is a top view illustrating a schematic configuration of a semiconductor device according to a sixth embodiment, FIG. 14B is a cross-sectional view taken along line D-D of FIG. 14A, and FIG. 14C is a cross-sectional view taken along line E-E of FIG. 14A.

Referring to FIGS. 14A to 14C, a fin-type P-channel field-effect transistor PM and a fin-type N channel field-effect transistor NM are provided on a semiconductor substrate 31. Also, the fin-type P-channel field-effect transistor PM and the fin-type N channel field-effect transistor NM may constitute a CMOS circuit.

In the case of the fin-type P-channel field-effect transistor PM, a fin-type semiconductor 33 is formed on the semiconductor substrate 31. The fin-type semiconductor 33 is formed so that the plane orientation of the fin side surface has a (110) plane and a (100) plane.

A buried insulation layer 32 is formed on the semiconductor substrate 31 so that the lower portion of the fin-type semiconductor 33 is buried. A punch-through stopper layer 34 is formed on the lower portion of the fin-type semiconductor 33.

In connection with the fin side surface of the fin-type semiconductor 33 protruding from the buried insulation layer 32, a channel region CP is formed on the (110) plane, and a source region SP and a drain region DP are formed on the (100) plane so as to interpose the channel region CP.

In the channel region CP, a gate electrode 36 is formed so as to interpose the fin-type semiconductor 33. Also, side wall spacers 37 are formed on side surfaces of the gate electrode 36.

Also, a semiconductor layer 38 is formed in the source region SP and the drain region DP so as to surround the fin-type semiconductor 33. A silicide layer 39 is formed on the outer layer of the semiconductor layer 38.

Meanwhile, in the case of the fin-type N channel field-effect transistor NM, a fin-type semiconductor 43 is formed on the semiconductor substrate 31. The fin-type semiconductor 43 is formed so that the plane orientation of the fin side surface has a (100) plane.

A buried insulation layer 32 is formed on the semiconductor substrate 31 so that the lower portion of the fin-type semiconductor 43 is buried. A punch-through stopper layer 44 is formed on the lower portion of the fin-type semiconductor 43.

In connection with the fin side surface of the fin-type semiconductor 43, which protrudes from the buried insulation layer 32, a channel region CN is formed on the (100) plane, and a source region SN and a drain region DN are formed so as to interpose the channel region CN.

In the channel region CN, a gate electrode 36 is formed so as to interpose the fin-type semiconductor 43. Also, side wall spacers 37 are formed on side surfaces of the gate electrode 36.

In the source region SN and the drain region DN, a semiconductor layer 48 is formed so as to surround the fin-type semiconductor 43. A silicide layer 49 is formed on the outer layer of the semiconductor layer 48.

Although a method of defining the channel region CP of the fin-type P-channel field-effect transistor PM by a (110) plane and defining the channel region CN of the fin-type N channel field-effect transistor NM by a (100) plane has been described with regard to the example of FIG. 14A, it is also possible to define both the channel region CP of the fin-type P-channel field-effect transistor PM and the channel region CN of the fin-type N channel field-effect transistor NM by a (110) plane.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a channel region formed on a first side surface of a fin-type semiconductor; and
a source/drain region formed on a second side surface, plane orientation of the second side surface being different from plane orientation of the first side surface, so that the channel region is interposed in the fin-type semiconductor.

2. The semiconductor device according to claim 1, wherein the plane orientation of the first side surface is a (110) plane, and the plane orientation of the second side surface is a (100) plane.

3. The semiconductor device according to claim 2, wherein the plane orientation has, by bending a fin side surface by 45° with regard to a fin side surface of the (110) plane, a (100) plane on the fin side surface so as to be continuous with the (110) plane.

4. The semiconductor device according to claim 3, wherein the fin-type semiconductor is configured in a loop shape so as to define a hexagon.

5. The semiconductor device according to claim 1, further comprising:
a gate insulation film formed in the channel region;
a gate electrode formed on the channel region via the gate insulation film so as to interpose the fin-type semiconductor from both sides;
a semiconductor layer formed on the source/drain region so as to surround the fin-type semiconductor; and
a silicide layer formed on an outer layer of the semiconductor layer.

6. The semiconductor device according to claim 1, further comprising a punch-through stopper layer provided on a lower portion of the fin-type semiconductor.

7. A semiconductor device comprising:
a fin-type P-channel field-effect transistor; and
a fin-type N channel field-effect transistor,
wherein the fin-type P-channel field-effect transistor is configured so that channel plane orientation of a fin side surface and source/drain plane orientation are different from each other.

8. The semiconductor device according to claim 7, wherein the fin-type N channel field-effect transistor is configured so that channel plane orientation of a fin side surface and source/drain plane orientation are different from each other.

9. The semiconductor device according to claim 8, wherein the channel plane orientation of the fin-type P-channel field-effect transistor and the fin-type N channel field-effect transistor is a (110) plane, and the source/drain plane orientation of the fin-type P-channel field-effect transistor and the fin-type N channel field-effect transistor is a (100) plane.

10. The semiconductor device according to claim 9, wherein the plane orientation has, by bending a fin side surface by 45° with regard to a fin side surface of the (110) plane, a (100) plane on the fin side surface so as to be continuous with the (110) plane.

11. The semiconductor device according to claim 10, wherein the fin-type semiconductor is configured in a loop shape so as to define a hexagon.

12. The semiconductor device according to claim 7, wherein the fin-type N channel field-effect transistor is configured so that channel plane orientation of a fin side surface and source/drain plane orientation are identical to each other.

13. The semiconductor device according to claim 12, wherein the channel plane orientation of the fin-type P-channel field-effect transistor is a (110) plane, and the channel plane orientation of the fin-type N channel field-effect transistor and the source/drain plane orientation of the fin-type P-channel field-effect transistor and the fin-type N channel field-effect transistor is a (100) plane.

14. The semiconductor device according to claim 7, wherein the fin-type P-channel field-effect transistor includes:
a channel region formed on a first fin side surface of the fin-type semiconductor; and
a source/drain region formed on a second fin side surface, plane orientation of the second fin side surface being different from plane orientation of the first fin side surface, so that, on the fin-type semiconductor, the channel region is interposed.

15. The semiconductor device according to claim 14, further comprising:
a gate insulation film formed in the channel region;
a gate electrode formed on the channel region via the gate insulation film so as to interpose the fin-type semiconductor from both sides;
a semiconductor layer formed on the source/drain region so as to surround the fin-type semiconductor; and
a silicide layer formed on an outer layer of the semiconductor layer.

16. The semiconductor device according to claim 15, further comprising a punch-through stopper layer provided on a lower portion of the fin-type semiconductor.

17. A method for manufacturing a semiconductor device, comprising:
forming a core pattern on a semiconductor substrate, the core pattern having an obtuse internal angle;
forming a side wall pattern on a side surface of the core pattern;
removing the core pattern while leaving the side wall pattern on the semiconductor substrate; and
forming a fin-type semiconductor on the semiconductor substrate by transferring the side wall pattern to the semiconductor substrate, the fin-type semiconductor having a (110) plane and a (100) plane on a side surface.

18. The method according to claim 17, wherein the core pattern is a hexagon.

19. The method according to claim 18, wherein four internal angles are set so that adjacent sides of the hexagon are bent by 45°, and remaining two opposite internal angles are set to be 90°.

20. The method according to claim 19, wherein the fin-type semiconductor is configured in a loop shape so as to define the hexagon.
